(19) United States
(12) Patent Application Publication
(10) Pub. No.: US 2005/0145836 A1
(43) Pub. Date: Jul. 7, 2005

(54) Influence of surface geometry

(76) Inventors: Avto Tavkhelidze, Tbilisi (GE); Amiran Bibilashvili, Tbilisi (GE); Rodney Thomas Cox, North Plains, OR (US)

Correspondence Address: Borealis Technical Limited, 23545 NW Skyline Blvd, North Plains, OR, 97133-9204, US

(21) Appl. No.: 10/991,257

(22) Filed: Nov. 16, 2004

Related U.S. Application Data
(63) Continuation-in-part of application No. 10/508,914, filed on Sep. 22, 2004.
(63) Continuation-in-part of application No. 10/760,697, filed on Jan. 19, 2004.
Application No. 10/760,697 is a division of application No. 09/634,615, filed on Aug. 5, 2000, now Pat. No. 6,680,214.
Application No. 10/760,697 is a continuation of application No. 09/093,652, filed on Jun. 8, 1998, now abandoned.
(60) Provisional application No. 60/366,563, filed on Mar. 22, 2002.
(60) Provisional application No. 60/366,546, filed on Mar. 25, 2002.
(60) Provisional application No. 60/373,508, filed on Apr. 17, 2002.
(60) Provisional application No. 60/149,805, filed on Aug. 18, 1999.

(51) Int. Cl. H01L 29/06

(52) U.S. Cl. 257/17

(57) ABSTRACT

This invention is a new class of materials having altered properties. In particular, materials having a surface structure causing electron De Broglie wave interference are described which result in a change in distribution of quantum states within the materials. The materials of the present invention have at least one surface having at least one indent or protrusion to cause electron De Broglie wave interference within the material.

### CROSS-REFERENCE TO RELATED APPLICATIONS

This application is a continuation-in-part application of application Ser. No. 10/508,914 filed Sep. 22, 2004, which is a U.S. national stage application of International Application PCT/US03/08907, filed Mar. 24, 2003, which international application was published on Oct. 9, 2003, as International Publication WO03083177 in the English language. The International Application claims the benefit of U.S. Provisional Application No. 60/366,563, filed Mar. 22, 2002, U.S. Provisional Application No. 60/366,564, filed Mar. 22, 2002, and U.S. Provisional Application No. 60/373,508, filed Apr. 17, 2002. This application is also a continuation-in-part application of application Ser. No. 10/760,697 filed Jan. 19, 2004 which is a divisional application of application Ser. No. 09/634,615, filed Aug. 5, 2000, now U.S. Pat. No. 6,680,214, which claims the benefit of U.S. Provisional Application No. 60/149,805, filed on Aug. 18, 1999, and is a continuation application of application Ser. No. 09/093,652, filed Jun. 8, 1998, now abandoned, and is related to application Ser. No. 09/020,654, filed Feb. 9, 1998, now U.S. Pat. No. 6,281,514. The above-mentioned patent applications are assigned to the assignee of the present application and are herein incorporated in their entirety by reference.

### BACKGROUND OF THE INVENTION

The present invention relates to methods for altering the distribution of quantum states within a volume limited by a potential energy barrier and for promoting the transfer of elementary particles across a potential energy barrier.

U.S. Pat. No. 6,281,514, U.S. Pat. No. 6,117,344, U.S. Pat. No. 6,531,703 and U.S. Pat. No. 6,495,843 disclose a method for promoting the passage of elementary particles through a potential barrier comprising providing a potential barrier having a geometrical shape for causing de Broglie interference between said elementary particles. Also disclosed is an elementary particle-emitting surface having a series of indents. The depth of the indents is chosen so that the probability wave of the elementary particle reflected from the bottom of the indent interferes destructively with the probability wave of the elementary particle reflected from the surface. This results in the increase of tunneling through the potential barrier. When the elementary particle is an electron, then electrons tunnel through the potential barrier, thereby leading to a reduction in the effective work function of the material.

WO03083177 discloses modification of a metal surface with patterned indents to increase the Fermi energy level inside the metal, leading to a decrease in electron work function. Also disclosed is a method for making nanostructured surfaces having perpendicular features with sharp edges.

### BRIEF SUMMARY OF THE INVENTION

In broad terms, this invention is a new class of materials having altered properties. In particular, it relates to materials having a surface structure causing electron wave interference resulting in a change in the way electron energy levels within the materials are distributed. The materials of the present invention have at least one surface having at least one indent or protrusion to cause electron wave interference within the material.

In a first embodiment the materials of the invention take the form of a substrate surface having at least one indent or protrusion to cause electron wave interference within the substrate. The substrate may be a metal or non-metal.

In a second embodiment the materials of the invention take the form of a thin layer of a substance on a substrate surface having at least one indent or protrusion to cause electron wave interference within the substance. The substance may be a metal or non-metal

### BRIEF DESCRIPTION OF THE SEVERAL VIEWS OF THE DRAWING

For a more complete explanation of the present invention and the technical advantages thereof, reference is now made to the following description and the accompanying drawing in which:

FIG. 1 shows a material of the present invention in the form of a substrate surface; and

FIG. 2 shows a material of the present invention in the form of a thin layer of a substance on a substrate surface.

### DETAILED DESCRIPTION OF THE INVENTION

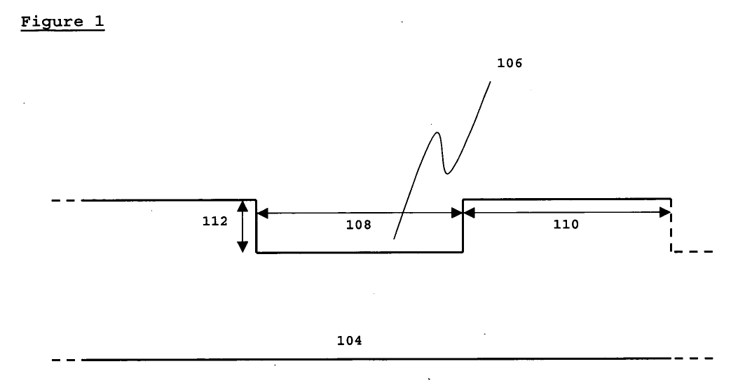

Embodiments of the present invention and their technical advantages may be better understood by referring to FIG. 1 which shows a substrate 104. The substrate has an indent 106 on one surface. Whilst the structure shown in FIG. 1 is a single indented region, this should not be considered to limit the scope of the invention, and dotted lines have been drawn to indicate that in further embodiments the structure shown may be extended in one or both directions (i.e. to the left and/or to the right) to form features on the surface of the substrate that have a repeating, or periodic, nature.

The configuration of the surface may resemble a corrugated pattern of squared-off, “u”-shaped ridges and/or valleys. Alternatively, the pattern may be a regular pattern of rectangular “plateaus” or “holes,” where the pattern resembles a checkerboard. The walls of said indents should be substantially perpendicular to one another, and the edges of the indents should be substantially sharp. Further, one of ordinary skill in the art will recognize that other configurations are possible that may produce the desired interference of wave functions. The surface configuration may be achieved using conventional approaches known in the art, including without limitation lithography and e-beam milling.

Substrate 104 is comprised of any material that can have its surface modified to form the indented structure illustrated in FIG. 1. Preferably the material is one that, under stable conditions, will not form an oxide layer, or will form an oxide layer of a known and reliable thickness. In any case, the thickness of an oxide layer formed on the material should be much less than the depth of the indent. Preferred materials include, but are not restricted to, metals such as gold and chrome, and materials that under stable conditions form an oxide layer preferably of less than about ten nanometers, and more preferably of less than about five nanometers. Other preferred materials include non-metals such as silica and silicon. In a preferred embodiment the material is substantially homogenous and has no internal atomic or molecular structure likely to interfere with electron De Broglie waves, and most preferably is monocrystalline or amorphous.

Indent 106 has a width 108 and a depth 112 and the separation between the indents is 110. Preferably distances 108 and 110 are substantially equal. Preferably distance 108 is of the order of 1 μm or less. Experimental observations using a Kelvin probe indicate that the magnitude of a reduction in an apparent work function increases as distance 112 is reduced. Utilization of e-beam lithography to create structures of the kind shown in FIG. 1 may allow indents to be formed in which distance 108 is 100 nm or less. Distance 112 is of the order of 10 nm or less, and is preferably of the order of 5 nm.

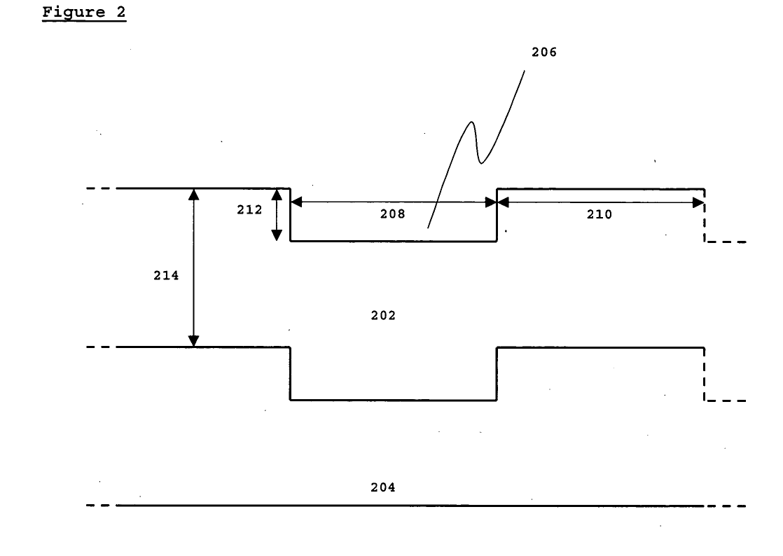

Referring now to FIG. 2, substrate 204 is the modified insulator substrate having geometry described above and shown in FIG. 1. Thin film 202 is formed on the indented surface as shown in FIG. 2. Thin film 202 may be deposited onto the surface of substrate 204 by any conventional means of deposition. Preferably film 202 is formed on substrate 204 by a process that does not lead to the formation of any internal atomic or molecular structure likely to interfere with electron waves, and most preferably film 202 is monocrystalline or amorphous. Film 202 is sufficiently thin that the structure of the substrate is maintained on the surface of the film. Thus distances 208, 210, and 212 are substantially similar to distances 108, 110, and 112. Distance 214 is typically of the order of 100 nm, and is preferably comparable to the ballistic range of an electron inside material 202. Film 202 is comprised of any material that can be formed on substrate 204 as illustrated in FIG. 2. Preferably the material is one that, under stable conditions, will not form an oxide layer, or will form an oxide layer of a known and reliable thickness. Preferred materials include, but are not restricted to, metals such as gold and chrome, and materials that under stable conditions form an oxide layer preferably of less than about ten nanometers, and more preferably of less than about five nanometers. Preliminary measurements show that using gold as the material may allow the apparent work function to be reduced to as little as 0.6 eV. Using calcium may allow a substantially greater reduction of work function. Other preferred materials include non-metals.

1. A material comprising a substantially plane slab of a substance having on one surface one or more indents of a depth less than approximately 10 nm and a width less than approximately 1 μm.

2. The material of claim 1 in which said depth is approximately 5 nm.

3. The material of claim 1 in which said width is less than approximately 100 nm.

4. The material of claim 1 in which walls of said indents are substantially perpendicular to one another.

5. The material of claim 1 in which edges of said indents are substantially sharp.

7. The material of claim 1 wherein said substance comprises an oxidation-resistant material.

8. The material of claim 1 wherein said substance is substantially homogenous.

9. The material of claim 1 wherein said substance is selected from the group consisting of: lead, tin, calcium, gold, silica and silicon.

10. The material of claim 1 wherein said substance is substantially free of granular irregularities.

11. The material of claim 1 wherein said substance is a monocrystal.

12. The material of claim 1 additionally comprising a thin film of a second substance formed on said surface.

13. The material of claim 12 in which a thickness of said film is less than approximately 100 nm.

14. The material of claim 12 wherein said second substance comprises an oxidation-resistant material.

15. The material of claim 12 wherein said second substance is substantially homogenous.

16. The material of claim 12 wherein said second substance is selected from the group consisting of: lead, tin, calcium, gold, silica and silicon.

17. The material of claim 12 wherein said second substance is substantially free of granular irregularities.

18. The material of claim 12 wherein said second substance is a monocrystal.
